(19) United States
(12) Patent Application Publication
(10) Pub. No.: US 2026/0181856 A1
(43) Pub. Date: Jun. 25, 2026

(54) HIGHLY-SCALABLE 2T MEMORY CELL AND METHOD OF MANUFACTURING THE SAME

(71) Applicants: EWHA UNIVERSITY - INDUSTRY COLLABORATION FOUNDATION, Seoul (KR); KONKUK UNIVERSITY INDUSTRIAL COOPERATION CORP, Seoul (KR)

(72) Inventors: Seongjae CHO, Seoul (KR); Hyunwoo Kim, Seoul (KR)

(73) Assignees: EWHA UNIVERSITY - INDUSTRY COLLABORATION FOUNDATION, Seoul (KR); KONKUK UNIVERSITY INDUSTRIAL COOPERATION CORP, Seoul (KR)

(21) Appl. No.: 19/395,227

(22) Filed: Nov. 20, 2025

(30) Foreign Application Priority Data
Dec. 20, 2024 (KR) 10-2024-0192933

(51) Int. Cl. H10B 12/00

(52) U.S. Cl. CPC H10B 12/00

(57) ABSTRACT

The present disclosure relates to a 2T memory cell, and more particularly to a technology including a first transistor that performs data write and erase operations and a second transistor that performs a data read operation. The first transistor is formed vertically above the second transistor, and the first drain of the first transistor serves as the second gate of the second transistor. The channel of the first transistor has a longer effective channel length than the channel of the second transistor. High-density integration is possible by forming the first transistor through a self-aligned process, and data retention characteristics are improved by forming the channel of the first transistor with a semiconductor material having a wide bandgap such as polysilicon or IGZO. The 2T memory cell according to the present disclosure can simultaneously achieve high-speed operation and high integration density.

### CROSS-REFERENCE TO RELATED APPLICATION

This application claims priority to Korean Patent Application No. No. 10-2024-0192933, filed on Dec. 20, 2024 in the Korean Intellectual Property Office, the disclosure of which is incorporated herein by reference.

### BACKGROUND OF THE DISCLOSURE

### Field of the Disclosure

The present invention relates to highly integrated semiconductor memory devices, and more particularly, to a 2T memory cell structure implemented by vertically stacking a first transistor that performs data write and erase operations and a second transistor that performs data read operations, and a technology for manufacturing the same through a self-aligned process.

### Description of the Related Art

As the semiconductor industry advances, the need for high-performance, highly integrated memory devices is increasing. Currently, widely used representative memory devices include DRAM (dynamic random-access memory) and SRAM (static random-access memory).

Each of these memory devices has its own advantages and disadvantages and is selectively used depending on the application field. However, they do not fully satisfy the market demand for recent high-performance, low-power, and highly integrated memory.

DRAM has a simple structure consisting of one transistor and one capacitor, which is advantageous for high integration. However, DRAM has the characteristic that stored data is destroyed during a read operation, which essentially requires a refresh operation to periodically recharge the data.

This refresh operation not only causes a reduction in memory bandwidth but also becomes a main cause of increased power consumption. In particular, since the stored data is inevitably destroyed during a read operation and an additional data restoration operation must be accompanied, there is a problem that the operating speed of the memory is degraded accordingly.

In addition, the capacitor of DRAM must be manufactured in a complex three-dimensional structure to secure sufficient charge storage capacity in fine processes, which is causing increased manufacturing costs and yield degradation.

SRAM typically consists of six transistors and has the advantage that a refresh operation is unnecessary and the operating speed is fast. However, it has the fundamental disadvantage that the cell area is large due to the multiple transistors.

In particular, in recent semiconductor technology trends where high integration is required, the large cell area of SRAM is becoming an important constraint. In addition, as transistor size decreases, characteristic non-uniformity problems due to process variations intensify, making it difficult to ensure stable operation.

In particular, in the case of SRAM, stable operation is possible only when the characteristics of all transistors are uniform, but in fine processes, it is becoming very difficult to secure such characteristic uniformity.

The conventional 2T DRAM proposed to solve these problems has a structure in which two transistors are arranged on a plane, has a smaller cell area than SRAM, and can eliminate the capacitor of 1T1C DRAM.

However, due to the planar structure, there is a limit to improving integration density, and in particular, there is a problem that operational reliability is degraded due to interference effects between the two transistors. In addition, it is difficult to sufficiently secure the channel length of the two transistors arranged on the plane, resulting in a problem of shortened data retention time, which consequently causes the need to shorten the refresh period.

In particular, in fine processes, as the channel length of transistors decreases, leakage current increases, resulting in a problem of further deterioration of data retention characteristics.

Furthermore, in the conventional 2T DRAM structure, as the two transistors are arranged on one plane, there is a problem of increased cell area, which becomes a constraint factor for high integration.

In addition, wiring connections between the two transistors become complex, making the manufacturing process difficult, which also causes problems of increased manufacturing costs and yield degradation. Moreover, in the planar structure, it is difficult to independently optimize the characteristics of transistors, resulting in a limitation that it is difficult to optimize the performance of write operations and read operations respectively.

Therefore, there is an urgent need to develop a new memory cell structure and manufacturing method thereof that enables integration in the vertical direction through a self-aligned process while having stable data storage characteristics, in order to overcome the limitations of these existing technologies.

In particular, there is a need to develop a vertically stacked 2T DRAM structure that can sufficiently secure the channel length of the write transistor to improve data retention characteristics, while enabling high-speed operation of the read transistor and minimizing cell area.

In addition, development of self-alignment-based manufacturing process technology that can stably implement such a vertical structure is also required.

This invention was supported by the National Research Foundation of Korea (NRF) funded by the Korean Ministry of Science and ICT (MSIT) through Grants 2022M3I7A1078936 and RS-2023-00258527.

“This patent was supported by the ‘Regional Innovation System & Education (RISE)’ through the Seoul RISE Center, funded by the Ministry of Education and the Seoul Metropolitan Government.” (2025-RISE-01-001-01)

### RELATED ART DOCUMENT

### Patent Document

U.S. Patent Publication No. 2024-0147686, “SEMICONDUCTOR MEMORY CELL STRUCTURE, SEMICONDUCTOR MEMORY, PREPARATION METHOD AND APPLICATION THEREOF”
U.S. Pat. No. 9,734,914, “METHOD FOR DRIVING A READING TRANSISTOR COUPLED TO AN OXIDE SEMICONDUCTOR WRITING TRANSISTOR”

### Non-Patent Document

M. Ansari, “Capacitorless 2T-DRAM for Higher Retention Time and Sense Margin”, IEEE TRANSACTIONS ON ELECTRON DEVICES, VOL. 67, NO. 3, pp. 902-906, March 2020.

### SUMMARY OF THE DISCLOSURE

Therefore, the present disclosure has been made in view of the above problems, and it is an object of the present disclosure to provide a 2T DRAM cell structure capable of high-density integration.

It is another object of the present disclosure to solve the data destruction problem that occurs during read operations of conventional DRAM, thereby improving memory bandwidth.

It is still another object of the present disclosure to provide a manufacturing method of a vertically stacked 2T DRAM cell that can be reliably implemented through a self-aligned process.

It is yet another object of the present disclosure to improve data retention characteristics by securing a sufficient effective channel length of the write transistor.

It is a further object of the present disclosure to provide a structure capable of independently optimizing the high-speed operation characteristics of the read transistor and the data retention characteristics of the write transistor.

It is still a further object of the present disclosure to provide a memory cell structure capable of stable operation while having a smaller cell area than SRAM.

It is yet a further object of the present disclosure to provide a manufacturing method that can be easily applied in industry by utilizing the existing gate-last process.

It is another object of the present disclosure to provide a manufacturing method capable of minimizing device-to-device alignment errors that may occur in a vertical stacked structure.

In accordance with an aspect of the present disclosure, the above and other objects can be accomplished by the provision of a 2T memory cell comprising: a first transistor including a first source, a first gate, and a first drain; and a second transistor formed on a substrate and including a second source, a second gate, and a second drain, wherein the first transistor is formed vertically above the second transistor, wherein the first drain of the first transistor operates as the second gate of the second transistor, wherein the first transistor performs data write and erase operations, and the second transistor performs data read operations, and wherein a channel of the first transistor has a longer effective channel length than a channel of the second transistor.

The channel of the first transistor may be formed of polysilicon or IGZO.

The second transistor may be formed on the bulk silicon substrate.

The channel of the first transistor may be formed vertically to extend the effective channel length.

The first transistor may be formed by a self-aligned process.

The channel of the first transistor may be formed of a semiconductor material having a wider energy bandgap than the channel of the second transistor.

In accordance with another aspect of the present disclosure, there is provided a method of manufacturing a 2T memory cell, the method comprising: sequentially forming a dummy oxide film, a dummy gate, and a hard mask on a substrate; patterning the dummy gate using the hard mask; forming a source and a drain of a second transistor on both sides of the patterned dummy gate; forming a source of a first transistor on upper portions of both sides of the dummy gate; removing the hard mask and the dummy gate to form an opening; forming a gate insulating film and a gate of the second transistor in the opening; forming a channel of the first transistor vertically on the gate of the second transistor, wherein the gate of the second transistor is formed to serve as a drain of the first transistor; and forming a gate insulating film and a gate of the first transistor on a side surface of the channel.

The method may further comprise performing ion implantation for adjusting a threshold voltage of the second transistor before forming the dummy oxide film on the substrate.

The channel of the first transistor may be formed of polysilicon or IGZO.

The method may further comprise forming an insulating film on an entire structure including the dummy gate and planarizing the insulating film after forming the source and the drain of the second transistor.

The step of forming the channel of the first transistor may be performed through a self-aligned process.

The source of the first transistor may be formed of doped polysilicon or a metal material. The channel of the first transistor may be formed to have a longer effective channel length than the channel of the second transistor.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 is a circuit diagram of a 2T memory cell according to an embodiment of the present disclosure.

FIG. 2 is a cross-sectional view of a 2T memory cell according to an embodiment of the present disclosure.

FIGS. 3 to 12 are cross-sectional views illustrating a manufacturing process of a 2T memory cell according to an embodiment of the present disclosure.

### DETAILED DESCRIPTION OF THE DISCLOSURE

The present disclosure will now be described more fully with reference to the accompanying drawings and contents disclosed in the drawings. However, the present disclosure should not be construed as limited to the exemplary embodiments described herein.

The terms used in the present specification are used to explain a specific exemplary embodiment and not to limit the present inventive concept. Thus, the expression of singularity in the present specification includes the expression of plurality unless clearly specified otherwise in context. It will be further understood that the terms “comprise” and/or “comprising”, when used in this specification, specify the presence of stated components, steps, operations, and/or elements, but do not preclude the presence or addition of one or more other components, steps, operations, and/or elements thereof.

It should not be understood that arbitrary aspects or designs disclosed in “embodiments”, “examples”, “aspects”, etc. used in the specification are more satisfactory or advantageous than other aspects or designs.

In addition, the expression “or” means “inclusive or” rather than “exclusive or”. That is, unless otherwise mentioned or clearly inferred from context, the expression “x uses a or b” means any one of natural inclusive permutations.

In addition, as used in the description of the disclosure and the appended claims, the singular forms “a”, “an” and “the” are intended to include the plural forms as well, unless context clearly indicates otherwise.

Although terms used in the specification are selected from terms generally used in related technical fields, other terms may be used according to technical development and/or due to change, practices, priorities of technicians, etc. Therefore, it should not be understood that terms used below limit the technical spirit of the present disclosure, and it should be understood that the terms are exemplified to describe embodiments of the present disclosure.

Also, some of the terms used herein may be arbitrarily chosen by the present applicant. In this case, these terms are defined in detail below. Accordingly, the specific terms used herein should be understood based on the unique meanings thereof and the whole context of the present disclosure.

Unless otherwise defined, all terms (including technical and scientific terms) used herein have the same meaning as commonly understood by one of ordinary skill in the art. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Meanwhile, in the following description of the present disclosure, a detailed description of known functions and configurations incorporated herein will be omitted when it may make the subject matter of the present disclosure unclear. The terms used in the specification are defined in consideration of functions used in the present disclosure, and can be changed according to the intent or conventionally used methods of clients, operators, and users. Accordingly, definitions of the terms should be understood on the basis of the entire description of the present specification.

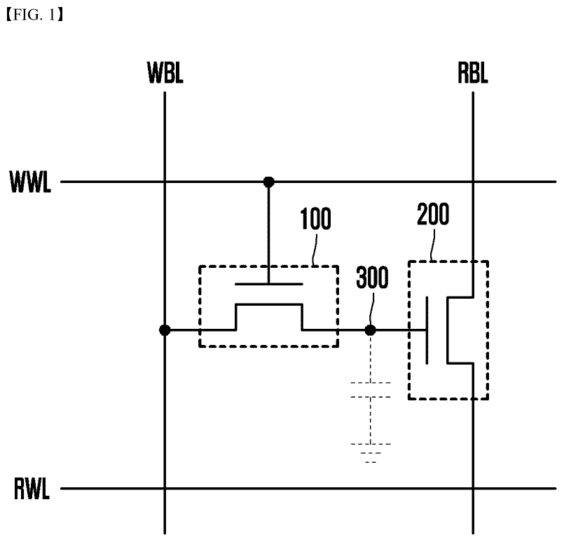

FIG. 1 is a circuit diagram of a 2T memory cell according to an embodiment of the present disclosure.

Referring to FIG. 1, the 2T memory cell according to an embodiment of the present disclosure includes a first transistor 100 and a second transistor 200, and may include a storage node 300 for storing data between the first transistor 100 and the second transistor 200.

The first transistor 100 serves as a write transistor for performing write and erase operations of data, with its gate controlled via WWL (write wordline) and connected to WBL (write bitline).

The drain of the first transistor 100 is electrically connected to the storage node 300 to store data. The first transistor 100 may have a longer effective channel length than the second transistor 200 to secure sufficient data retention time.

The channel of the first transistor 100 may be formed of a semiconductor material having a wide bandgap, such as polysilicon or IGZO, to minimize leakage current. In particular, when IGZO is used as a channel material, leakage current in an off state can be significantly reduced due to a wider bandgap compared to silicon.

The drain of the first transistor 100 may simultaneously serve as the gate of the second transistor 200.

The second transistor 200 is a read transistor that performs a read operation of data, wherein a gate thereof may be controlled by RWL (read wordline) and may be connected to RBL (read bitline).

The gate of the second transistor 200 is electrically connected to the storage node 300, and the conduction state of the second transistor 200 may be controlled according to the data value stored in the storage node 300.

The second transistor 200 may have a shorter channel length than the first transistor 100 for high-speed read operations. The second transistor 200 may be formed directly on a silicon substrate to secure high charge mobility and excellent electrical characteristics.

The storage node 300 is located between the first transistor 100 and the second transistor 200 to store data.

The storage node 300 may be formed of doped polysilicon or a metal material to have excellent electrical conductivity.

Hereinafter, the operation of the 2T memory cell according to an embodiment of the present disclosure will be described in more detail.

During a write operation, a positive voltage (in the case of NMOS) or a negative voltage (in the case of PMOS) for turning on the first transistor 100 is applied to WWL, and a voltage corresponding to the data value to be stored is applied through WBL. For example, to write logic “1”, a power supply voltage (V_{DD}) may be applied to WBL, and to write logic “0”, a ground voltage (V_{SS}) may be applied.

At this time, the first transistor 100 is turned on so that the voltage of WBL can be transferred to the storage node 300. After the write operation is completed, by deactivating WWL to turn off the first transistor 100, the storage node 300 can retain the charge.

During a read operation, the data value stored in the storage node 300 can be determined by activating RWL to check whether the second transistor 200 is conducting. When logic “1” is stored in the storage node 300, the second transistor 200 becomes conductive and current can flow through RBL.

Conversely, when logic “0” is stored in the storage node 300, the second transistor 200 maintains a cutoff state so that current flow through RBL can be blocked. Since this read operation does not change the gate voltage of the second transistor 200, it can be performed as a non-destructive read operation that does not destroy the data stored in the storage node 300.

Due to the long channel length of the first transistor 100 and the use of a wide bandgap channel material, the charge in the storage node 300 can be retained for a long time.

In addition, due to the short channel length and silicon-based structure of the second transistor 200, high-speed read operations can be possible. In particular, since the read operation is performed non-destructively, unlike conventional DRAM, a restore process after the read operation is unnecessary, thereby improving operation speed and reducing power consumption.

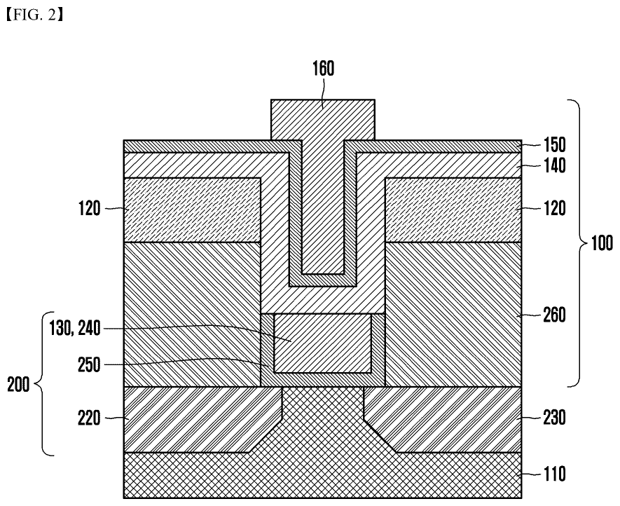

FIG. 2 is a cross-sectional view of a 2T memory cell according to an embodiment of the present disclosure.

Referring to FIG. 2, the 2T memory cell according to an embodiment of the present disclosure may include a second transistor 200 formed on a substrate 110 and a first transistor 100 formed vertically above the second transistor 200.

The second transistor 200 may be formed on the substrate 110 made of bulk silicon. The substrate 110 may be formed of a single crystal silicon wafer, and ion implantation for threshold voltage adjustment may be performed in the channel region of the second transistor 200.

The substrate 110 may be formed of a single crystal silicon wafer. The thickness of the substrate 110 may typically be selected within a range of 300-800 μm, and the crystal orientation may have a (100) or (111) direction.

The resistivity of the substrate 110 may be selected within a range of 1-100 Ω·cm, and may be doped with p-type or n-type dopants. In particular, a well region may be formed on the surface of the substrate 110 for forming the second transistor 200, which may be formed by implanting impurities such as boron (B), phosphorus (P), and arsenic (As) at a concentration of 10¹⁵-10¹⁹/cm³.

The second transistor 200 may include a second source 220 and a second drain 230. The second source 220 and the second drain 230 are highly doped impurity regions and may be formed in the surface region of the substrate 110.

The second transistor 200 may have a structure optimized for high-speed read operations.

The second source 220 and the second drain 230 are high-concentration impurity regions formed in the surface region of the substrate 110, which may be formed through an ion implantation process, and the impurity concentration may be controlled within a range of 10¹⁹-10²¹/cm³.

A second gate insulating film 250 may be formed on the channel region between the second source 220 and the second drain 230. The second gate insulating film 250 may be formed of an insulating material such as silicon oxide (SiO₂), silicon nitride (SiNₓ), or a high-k dielectric

Depending on the embodiment, the second gate insulating film 250 may be formed of various insulating materials. In the case of silicon oxide (SiO₂), it can be formed with a thickness of 1-10 nm, and in the case of silicon nitride (SiNₓ), it can be formed with a thickness in a range of 2-20 nm. In addition, high-k dielectrics such as HfO₂, Al₂O₃, and ZrO₂ may be formed alone or in a stacked structure thereof. In particular, when a high-k dielectric is used, the equivalent oxide thickness (EOT) can be reduced to 1-3 nm while effectively suppressing gate leakage current.

A second gate 240 may be formed on the second gate insulating film 250. The second gate 240 may be formed of doped polysilicon or a metal material, and may simultaneously serve as the first drain 130 of the first transistor 100 in a subsequent process. For this purpose, the second gate 240 may be formed to have sufficient electrical conductivity.

Since the second gate 240 simultaneously serves as the first drain 130 of the first transistor 100, the second gate 240 may be formed of doped polysilicon, and in this case, the impurity concentration may be controlled in a range of 10¹⁹-10²¹/cm³, but is not limited thereto and may have an appropriate concentration for device operation.

When the second gate 240 serving as the first drain 130 is formed of a metal material for optimization of electrical characteristics, the work function may be selected in a range of 4.0-5.3 eV, and the resistivity may be optimized in a range of 15-50 μΩ·cm. At this time, since the interface characteristics between the metal material and the channel directly affect the electrical performance, an appropriate metal material may be selected in consideration of the metal-semiconductor junction characteristics at the interface.

In addition, the second gate 240 may be formed as a metal gate, and may be formed of a single metal layer such as TiN, TaN, W, and WN, or a stacked structure thereof. The second gate 240 may have a sufficient thickness to minimize resistance.

The insulating film 260 may be formed for electrical isolation between the second transistor 200 and the first transistor 100. Depending on the embodiment, the insulating film 260 may be formed of silicon oxide, silicon nitride, or a stacked structure thereof.

The insulating film 260 may have a sufficient thickness to prevent interlayer interference, and in particular, since the dielectric constant of the insulating film 260 affects leakage current characteristics and parasitic capacitance, it may be optimized in consideration of the operating characteristics of the device.

The insulating film 260 may be formed in a stacked structure of silicon oxide and silicon nitride, and the thickness of each layer may be, for example, a lower oxide layer of 20-50 nm, an intermediate nitride layer of 30-100 nm, and an upper oxide layer of 20-50 nm, so that the total thickness can be maintained at 70-200 nm. This multilayer structure can relieve mechanical stress and improve insulating characteristics.

The first transistor 100 may be formed vertically above the second transistor 200 through a self-aligned process. The first transistor 100 may include a first source 120, a first drain 130, and a first gate 160.

The first source 120 may be formed on both upper sides of the insulating film 260. The first source 120 may be formed of doped polysilicon or a metal material such as tungsten (W), titanium (Ti), and tantalum (Ta), and may be formed to have sufficient electrical conductivity.

Depending on the embodiment, when the first source 120 is formed of polysilicon, n-type or p-type impurities may be doped at a concentration of 10¹⁹-10²¹/cm³. As the metal material, W, Ti, Ta, or nitrides thereof may be used, and may be formed in a single layer or multilayer structure. The thickness of the first source 120 may be selected in a range of 30-150 nm.

The first gate 160 is formed on the side and upper surfaces of the first channel 140, and is insulated from the first channel 140 with the first gate insulating film 150 interposed therebetween. The first gate 160 may be formed of doped polysilicon or a metal material.

When the first gate 160 is formed as a metal gate, it may be formed of a single metal layer such as TiN, TaN, W, and WN, or a stacked structure thereof, in consideration of work function. The thickness of the first gate 160 may be selected in a range of 30-150 nm, and may have an appropriate thickness to minimize gate resistance.

The first gate 160 may be formed symmetrically with respect to both sides of the first channel 140, and can effectively control the first channel 140. This structure can improve gate controllability to secure stable switching characteristics even at relatively low operating voltages.

In addition, the first gate 160 may be formed with a uniform thickness along the entire side surface of the first channel 140 so that the gate electric field can be uniformly applied to the channel in the vertical channel structure.

The first channel 140 may be formed vertically on the second gate 240 and connected to the first source 120. The first channel 140 may be formed of a semiconductor material having a wide bandgap, such as polysilicon or IGZO.

The first channel 140 is formed in a vertical direction to secure a long effective channel length. The length of the first channel 140 may be adjusted in a range of 50-300 nm, and the channel width may be optimized in a range of 20-100 nm.

Depending on the embodiment, when IGZO is used as the channel material of the first channel 140, the composition ratio of In:Ga:Zn may be adjusted in a range from 1:1:1 to 2:2:1, and the oxygen content may be precisely controlled as it directly affects the leakage current characteristics.

For example, when the first channel 140 is formed of IGZO, since the bandgap is 3.2 eV, which is much larger than that of silicon (1.12 eV), leakage current in the off state can be significantly reduced. The charge mobility of the IGZO channel may be controlled in a range of 10-20 cm²/V·s, and can exhibit stable electrical characteristics despite being an amorphous structure. The IGZO channel may be formed by crystal growth techniques including sputtering, atomic layer deposition (ALD), or metal-organic chemical vapor deposition (MOCVD), and the electrical characteristics may be optimized through subsequent heat treatment.

To secure a process margin in the vertical structure, the aspect ratio of the first channel 140 may be optimized in a range of 2:1 to 20:1, which may be appropriately selected for deposition uniformity and control of etching profile during channel formation.

In particular, in the vertical channel structure, thickness uniformity at the top and bottom of the channel is very important, and the aspect ratio of the first channel 140 may be controlled with a deviation within 3-5%.

In particular, in the vertical channel structure, thickness uniformity at the top and bottom of the channel is very important, and the aspect ratio of the first channel 140 may be controlled with a deviation within 3-5%.

The first gate insulating film 150 is formed along the side and upper surfaces of the first channel 140, and the gate insulation characteristics may directly affect the data retention time. The first gate insulating film 150 may be formed of silicon oxide, silicon nitride, or a high-k dielectric.

Materials such as HfO₂, Al₂O₃, and ZrO₂ may be used as the high-k dielectric, and their dielectric constants are 25, 9, and 23, respectively. The thickness of the first gate insulating film 150 may be physically formed in a range of 3-15 nm, and the equivalent oxide thickness may be optimized in a range of 1-3 nm.

An insulating film 260 is formed between the second transistor 200 and the first transistor 100 to electrically isolate the two transistors. The insulating film 260 may be formed of an insulating material such as silicon oxide and silicon nitride, and may be formed with a sufficient thickness to prevent electrical interference between the second transistor 200 and the first transistor 100.

The first transistor 100 performs data write and erase operations, and the second transistor 200 may perform data read operations. The first transistor 100 may have excellent data retention characteristics due to the long effective channel length from the vertical channel structure and the use of a wide bandgap channel material.

The second transistor 200 may be capable of high-speed read operations because it is formed directly on bulk silicon and has high charge mobility.

In the 2T memory cell according to an embodiment of the present disclosure, during a read operation, the conduction state of the second transistor 200 is determined according to the data value stored in the first transistor 100. Since the second gate 240 serves as the first drain 130 of the first transistor 100, the gate voltage of the second transistor 200 may be controlled by the charge stored through the first transistor 100.

The second transistor 200 may have high charge mobility because it is formed directly on the bulk silicon substrate 110. This high charge mobility enables high-speed read operations and can shorten the read operation time. In addition, the threshold voltage of the second transistor 200 may be precisely controlled through ion implantation.

The vertical channel structure of the first transistor 100 is formed through a self-aligned process. This self-aligned structure can minimize alignment errors between the second gate 240 and the first channel 140.

In particular, by forming the first channel 140 vertically on the second gate 240, the channel length can be extended without increasing the cell area in the planar direction. This extended long channel length can be effective in suppressing short channel effects and reducing leakage current.

In addition, the first gate insulating film 150 between the first gate 160 and the first channel 140 has a controlled interface trap density to minimize threshold voltage variation and can control gate leakage current. In particular, when an IGZO channel is used, an additional heat treatment in an oxygen atmosphere at a temperature in a range of 300-400° C. may be performed after channel formation to optimize interface characteristics with the gate insulating film.

In addition, the read operation through the second transistor 200 may be performed as a non-destructive read method that does not destroy the stored data. This is possible because the second gate 240 serves as the first drain 130 of the first transistor 100, enabling high-speed operation without an additional restore process.

The 2T memory cell according to an embodiment of the present disclosure enables integration in the vertical direction through a self-aligned process, thereby significantly reducing the cell area compared to the planar structure.

In addition, the 2T memory cell according to an embodiment of the present disclosure can independently optimize the channel structures and materials of the first transistor 100 and the second transistor 200, thereby simultaneously securing excellent data retention characteristics and high-speed operation characteristics. In particular, the vertical channel structure of the first transistor 100 enables securing a long effective channel length without increasing the cell area in the planar direction.

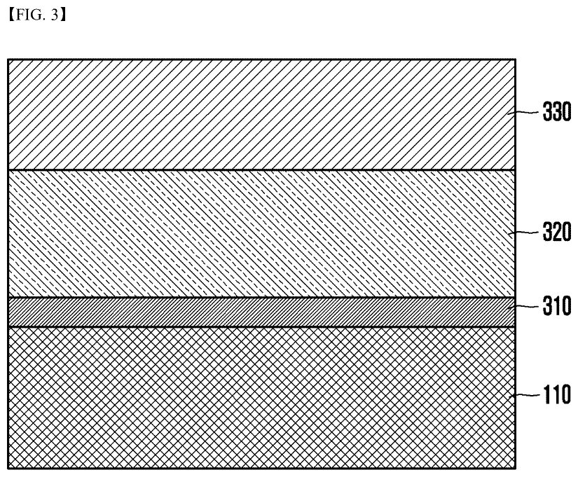

FIGS. 3 to 12 are cross-sectional views illustrating a manufacturing process of a 2T memory cell according to an embodiment of the present disclosure.

Referring to FIG. 3, as an initial process step for forming the second transistor 200, a structure in which a dummy oxide film 310, a dummy gate 320, and a hard mask 330 are sequentially stacked may be included on the substrate 110 on which the second transistor 200 including the second source 220, the second gate 240, and the second drain 230 will be formed.

Specifically, an ion implantation process for adjusting the threshold voltage of the second transistor 200 may be performed on the substrate 110 on which the channel of the second transistor 200 will be formed. The ion implantation process is for optimizing the operating characteristics of the second transistor 200, and the type of ions to be implanted, the dose, the implantation energy, and the like may be adjusted according to the required threshold voltage value of the second transistor 200.

In particular, since the second transistor 200 performs a data read operation, the threshold voltage may be adjusted to enable high-speed read operations.

The method of manufacturing a 2T memory cell according to an embodiment of the present disclosure may form a dummy oxide film 310 on the substrate 110 after the ion implantation process. The dummy oxide film 310 may be formed through a thermal oxidation process or a chemical vapor deposition process, and may perform a function of improving interface characteristics between the substrate 110 and the dummy gate 320 and protecting the substrate 110.

The thickness of the dummy oxide film 310 may be determined in consideration of the characteristics of the second gate insulating film 250 to be formed in a subsequent process.

The method of manufacturing a 2T memory cell according to an embodiment of the present disclosure may deposit a dummy gate 320 on the dummy oxide film 310.

The dummy gate 320 may be formed through a chemical vapor deposition process or a physical vapor deposition process, and may be removed in a subsequent process to provide a space in which the gate of the second transistor 200 will be formed.

The thickness of the dummy gate 320 may determine the gate length of the second transistor 200. In particular, since the second transistor 200 performs a data read operation, the thickness of the dummy gate 320 may be adjusted to have a short channel length.

The method of manufacturing a 2T memory cell according to an embodiment of the present disclosure may deposit a hard mask 330 on the dummy gate 320. The hard mask 330 may be formed of a nitride-based material, and may be used as an etching mask for patterning the dummy gate 320 in a subsequent process. The thickness of the hard mask 330 may be determined in consideration of resistance in a subsequent etching process.

According to an embodiment of the present disclosure, the stacked structure of the dummy oxide film 310, the dummy gate 320, and the hard mask 330 may form an initial structure of a gate-last process. This gate-last process is a process method suitable for fabricating high-performance transistors, and can prevent degradation of the gate material and improve interface characteristics by removing the dummy gate and forming an actual gate in a subsequent process.

This can ultimately improve the operating characteristics of the 2T memory cell composed of the first transistor 100 and the second transistor 200.

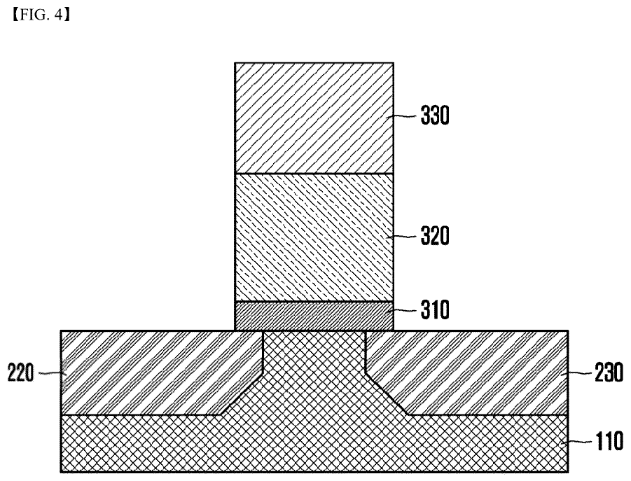

FIG. 4 is a cross-sectional view illustrating a dummy gate patterning and source/drain formation step in a method of manufacturing a 2T memory cell according to an embodiment of the present disclosure.

Referring to FIG. 4, the method of manufacturing a 2T memory cell according to an embodiment of the present disclosure may form regions of the source 220 and the drain 230 of the second transistor 200 on both sides of the patterned dummy gate 320 after patterning the dummy gate 320 using the hard mask 330.

Specifically, the method of manufacturing a 2T memory cell according to an embodiment of the present disclosure may anisotropically etch the dummy gate 320 using the hard mask 330 as an etching mask.

The anisotropic etching process may be performed by a reactive ion etching process using halogen-based gases such as CF₄, CHF₃, and Cl₂. The etching conditions may be set so that the etching selectivity between the dummy gate 320 and the dummy oxide film 310 is 10:1 or more, and the etching pressure may be controlled in a range of 10-100 mTorr. This etching selectivity and etching pressure are not limited thereto, and may vary depending on the type of material and the process environment.

Through the anisotropic etching process, a patterned dummy gate structure having vertical sidewalls may be formed.

After the dummy gate patterning process, an impurity ion implantation process for forming the source 220 and the drain 230 of the second transistor 200 may be performed in both side regions of the substrate 110 of the patterned dummy gate structure. When the second transistor 200 is an NMOS, phosphorus (P) or arsenic (As) ions may be implanted at a dose of 1×10¹⁵-5×10¹⁵ ions/cm². On the other hand, in the case of PMOS, boron (B) ions may be implanted at a dose in the same range. The ion implantation energy may be set in a range of 10-50 keV, which may be adjusted according to the desired junction depth.

The source 220 and drain 230 regions may be formed in an LDD (lightly-doped drain) structure. To this end, after first performing low-concentration ion implantation, spacers may be formed on the sidewalls of the dummy gate structure, and high-concentration ion implantation may be performed. The impurity concentration of the low-concentration region may be formed in a range of 1×10¹⁸-1×10¹⁹ atoms/cm³, and the impurity concentration of the high-concentration region may be formed in a range of 1×10²⁰-1×10²¹ atoms/cm³.

The method of manufacturing a 2T memory cell according to an embodiment of the present disclosure may further perform a heat treatment process for activating the implanted impurities after the impurity ion implantation process.

In the case of a rapid thermal annealing process, it may be performed for 10-60 seconds in a temperature range of 900-1,100° C., and in the case of a laser annealing process, it may be performed with an energy density of 0.1-1 J/cm². Through this heat treatment process, the activation rate of impurities can be increased to 90% or more.

According to an embodiment of the present disclosure, the channel length of the second transistor 200 may be determined by patterning of the dummy gate 320. For high-speed read operations of data, the channel length may be set in a range of 20-100 nm.

The junction depth of the source 220 and drain 230 regions may be formed in a range of 50-150 nm, which may be controlled to an optimized value in consideration of alignment with the vertical channel structure of the first transistor 100 to be formed in a subsequent process.

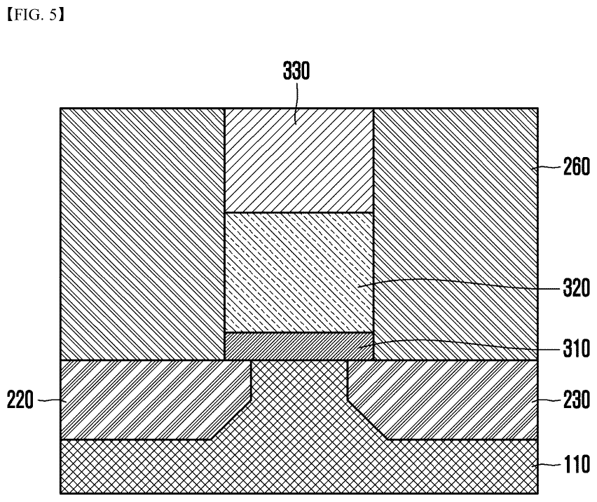

FIG. 5 is a cross-sectional view illustrating an insulating film deposition and planarization step in a method of manufacturing a 2T memory cell according to an embodiment of the present disclosure.

Referring to FIG. 5, the method of manufacturing a 2T memory cell according to an embodiment of the present disclosure may include a process of depositing and planarizing an insulating film 260 on the structure shown in FIG. 4 including the dummy gate 320.

Specifically, the method of manufacturing a 2T memory cell according to an embodiment of the present disclosure may deposit an insulating film 260 on the entire surface of the substrate 110 on which the source 220 and the drain 230 of the second transistor 200 are formed.

Depending on the embodiment, the insulating film 260 may be formed of silicon oxide using TEOS (Tetraethylorthosilicate) as a precursor, silicon nitride (Si₃N₄) formed by LPCVD process, USG (undoped silicate glass), PSG (phosphosilicate glass), BPSG (borophosphosilicate glass), FSG (fluorinated silicate glass), or low dielectric constant insulating materials such as SiOC and SiCN having a k (electrical permittivity) value of 3.0 or less, or a combination thereof, but is not limited thereto and may be appropriately controlled according to the process environment.

The deposition of the insulating film 260 in the method of manufacturing a 2T memory cell according to an embodiment of the present disclosure may be performed through a chemical vapor deposition (CVD) process in a temperature range of 300-400° C. and a pressure range of 1-10 Torr. At this time, the flow rate ratio of TEOS and O₂/O₃ may be adjusted to 1:5-1:10, but is not limited thereto and may be appropriately controlled according to the process environment.

In addition, an atomic layer deposition (ALD) process may be used for the deposition of the insulating film 260 in the method of manufacturing a 2T memory cell according to an embodiment of the present disclosure. For example, in a temperature range of 150-250° C., the pulse time of the silicon precursor and the oxidizing agent may be set to 0.5-2 seconds, respectively, and the purge time may be set to 3-10 seconds.

When a high-density plasma chemical vapor deposition (HDP-CVD) process is used for the deposition of the insulating film 260 in the method of manufacturing a 2T memory cell according to an embodiment of the present disclosure, the RF power may be set in a range of 2,000-4,000W and the bias power may be set in a range of 1,000-3,000W in a pressure range of 2-10 mTorr, but is not limited thereto and may be appropriately controlled according to the process environment.

The method of manufacturing a 2T memory cell according to an embodiment of the present disclosure includes a step of planarizing the deposited insulating film 260 through a chemical mechanical polishing (CMP) process. The slurry used in the CMP process may include a silica-based (50-150 nm particles) or ceria-based (100-200 nm particles) abrasive in a pH range of 7-11, and the concentration of the abrasive may be adjusted to 10-30 wt %. The slurry may also include a surfactant (0.01-0.1 wt %) and an oxidizing agent (0.1-1.0 wt %), and the slurry supply rate may be set in a range of 100-300 ml/min, and the above-mentioned values are not limited thereto and may be appropriately controlled according to the process environment.

In addition, depending on the embodiment, the CMP process may be performed in two stages. In the first stage, bulk polishing of the insulating film 260 may be performed at a pressure of 3-5 psi, a platen rotation speed of 40-60 rpm, and a carrier rotation speed of 35-55 rpm. In the second stage, precision polishing may be performed at a pressure of 1-3 psi, a platen rotation speed of 30-50 rpm, and a carrier rotation speed of 25-45 rpm until the surface of the hard mask 330 is exposed.

After the CMP process, the local step height of the insulating film 260 may be controlled to 5 nm or less within the wafer, and the global step height may be controlled to 10 nm or less. This is a value that falls within the alignment margin (±10 nm) of the vertical channel structure of the first transistor 100 to be formed in a subsequent process, thereby securing the reliability of the self-aligned process. The local step height and global step height are exemplary ranges and are not limited thereto and may be appropriately controlled to secure the reliability of the self-aligned process.

Depending on the embodiment, a cleaning process may be performed after the polishing. The cleaning process may be performed using an SPM (H₂SO₄:H₂O₂=4:1) solution at 60-70° C. for 5-10 minutes. Subsequently, additional cleaning may be performed using an SC-1 solution having a composition of NH₄OH:H₂O₂:H₂O=1:1:5 at 50-60° C. for 3-5 minutes. Finally, deionized water rinse may be repeated 3-5 times, and spin drying may be performed at a speed of 2,000-3,000 rpm for 30-60 seconds.

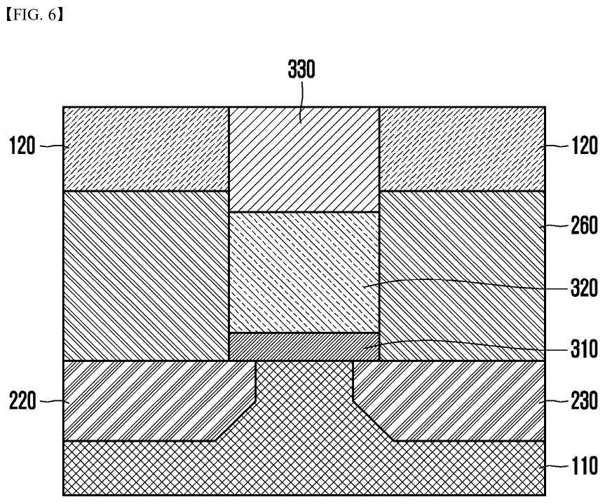

FIG. 6 is a cross-sectional view illustrating a step of etching back the insulating film and forming a first source of a first transistor in a method of manufacturing a 2T memory cell according to an embodiment of the present disclosure.

Referring to FIG. 6, the method of manufacturing a 2T memory cell according to an embodiment of the present disclosure may include etching back a specific region of the insulating film 260, and a thin film deposition and separation process for forming a source region of the first transistor 100, which is an upper transistor.

Specifically, the method of manufacturing a 2T memory cell according to an embodiment of the present disclosure may secure a space for forming the source 120 of the first transistor 100 by etching back the upper region of the insulating film 260.

Depending on the embodiment, the etch-back of the insulating film 260 may be performed by dry etching using fluorine-based gases such as CF₄ and CHF₃, or wet etching using a diluted HF solution. In the case of dry etching, the RF power may be set to 500-1,000W in a pressure range of 10-50 mTorr. In addition, in the case of wet etching, it may be performed at 23-27° C. using a solution diluted at a ratio of HF:H₂O=1:100-1:200, but the process conditions are not limited thereto and may be appropriately controlled according to the process environment.

The depth of the etch-back may be adjusted in a range of 100-200 nm, which is directly related to the thickness of the first source 120 to be formed in a subsequent process. The etching profile may be controlled to have an inclination angle of 80-85 degrees, which can improve the step coverage of a subsequent thin film deposition process.

The method of manufacturing a 2T memory cell according to an embodiment of the present disclosure may deposit a thin film for forming the first source 120. The first source 120 may be formed of polysilicon doped with phosphorus (P) or boron (B) at a concentration of 1×10¹⁹-1×10²¹ atoms/cm³, or a metal/metal nitride stacked structure such as Ti, TiN, W, and WN.

Depending on the embodiment, when the first source 120 is doped polysilicon, it may be deposited at 550-620° C. through an LPCVD process, and when the first source 120 is a metal material, it may be deposited at 300-400° C. through a sputtering or CVD process, but is not limited thereto and may be appropriately controlled according to the environment in which the process is performed.

The deposited thin film of the first source 120 may be separated through anisotropic etching to form individual source regions. The anisotropic etching may be performed using chlorine-based gases such as Cl₂ and BCl₃ in a pressure range of 5-20 mTorr, and the RF power may be set to 300-700W. The etching endpoint may be detected through optical emission spectroscopy.

In a subsequent process, the first source 120 may form a stable electrical contact with the vertical channel structure of the first transistor 100, which can improve the write operation reliability of the 2T memory cell.

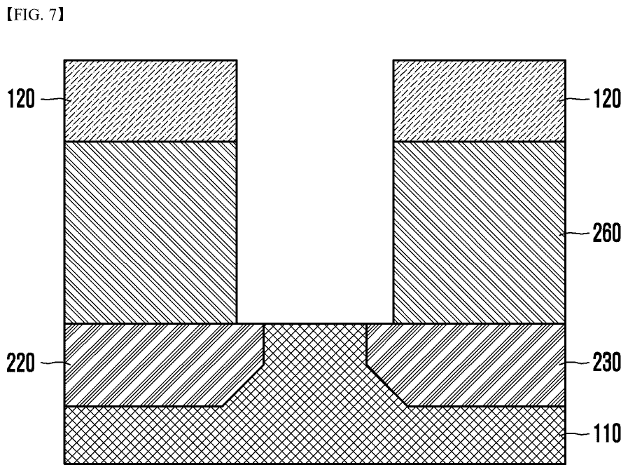

FIG. 7 is a cross-sectional view illustrating a step of forming an opening for forming a gate of a second transistor in a method of manufacturing a 2T memory cell according to an embodiment of the present disclosure.

Referring to FIG. 7, the second source and the second drain 230 of the second transistor 200 are formed in the substrate 110, and these junction regions may define the channel region of the second transistor.

The insulating film 260 may be formed on both sides to electrically insulate the gate structure to be formed in a subsequent process. The insulating film 260 is in a planarized state after being deposited following the formation of the dummy gate structure as shown in FIG. 5.

The method of manufacturing a 2T memory cell according to an embodiment of the present disclosure may include sequential etching processes.

First, the method of manufacturing a 2T memory cell according to an embodiment of the present disclosure selectively removes the upper hard mask 330 through wet etching. The hard mask 330 shown in FIG. 5 serves as a mask for pattern formation in previous processes, and then removes the dummy gate 320.

Depending on the embodiment, the dummy gate 320 is mainly formed of a material such as polysilicon, and the removal of the dummy gate 320 may be performed through selective etching.

Thereafter, the method of manufacturing a 2T memory cell according to an embodiment of the present disclosure removes the dummy oxide film 310.

The opening formed through the series of etching processes of the method of manufacturing a 2T memory cell according to an embodiment of the present disclosure may have a self-aligned structure.

The self-aligned structure allows the gate of the second transistor 200 to be accurately formed on the channel region, and enables accurate vertical alignment between the first transistor 100 and the second transistor 200. The gate 240 of the second transistor 200 to be formed in a subsequent process will simultaneously serve as the drain 130 of the first transistor.

The insulating film 260 serves as a sidewall protection film during these etching processes to enable selective etching of only the desired portions, and can simultaneously play a dual role of ensuring electrical isolation of the gate structure to be formed in a subsequent process.

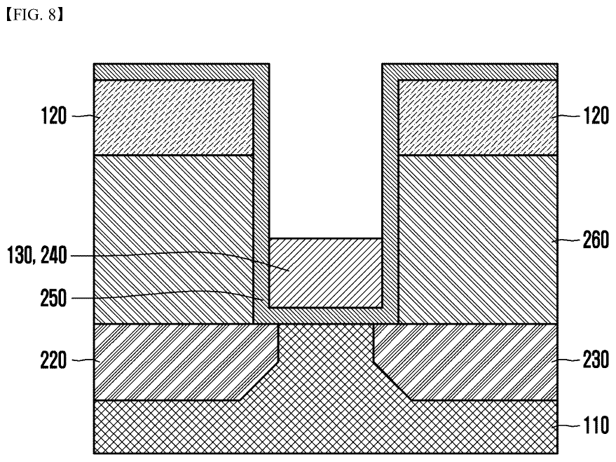

FIG. 8 is a cross-sectional view illustrating a step of forming the second gate insulating film 250 and the second gate 240 of the second transistor 200 in a method of manufacturing a 2T memory cell according to an embodiment of the present disclosure.

Referring to FIG. 8, the method of manufacturing a 2T memory cell according to an embodiment of the present disclosure forms the second gate insulating film 250 over the entire interior of the opening formed by sequentially removing the hard mask 330, the dummy gate 320, and the dummy oxide film 310 shown in FIG. 7.

The second gate insulating film 250 may be formed of a silicon oxide film through a thermal oxidation process, a high dielectric constant material using an atomic layer deposition method, or a composite stacked structure thereof.

The second gate insulating film 250 is responsible for electrical insulation between the gate and the channel, and may be formed with an appropriate thickness so that channel control by the gate electric field can be effectively achieved.

The method of manufacturing a 2T memory cell according to an embodiment of the present disclosure may form the second gate 240 only on the upper portion of the second gate insulating film 250.

Depending on the embodiment, the second gate 240 may be formed in the structure shown in FIG. 8 through an etching process after depositing doped polysilicon or a metal material to fill the opening.

Depending on the embodiment, when the second gate 240 uses a metal material, it may be formed in a stacked structure of a work function metal layer for work function adjustment and a low-resistance metal, which can contribute to threshold voltage control and operation speed improvement of the device.

The second gate 240 not only serves as the gate electrode of the second transistor 200, but also operates as the first drain 130 of the first transistor 100 to be formed in a subsequent process, thereby simultaneously performing the role of the first drain 130.

The insulating film 260 may be formed of silicon oxide, silicon nitride, or a combination thereof, and can electrically insulate the second gate 240 structure. In addition, the insulating film 260 is responsible for electrical insulation with the first transistor 100 structure to be formed in a subsequent process, and ensures stable operation of the entire device.

The structure formed by the self-aligned method shown in FIG. 8 ensures that the second gate 240 is accurately aligned with the channel region, and improves the electrical characteristics and reliability of the device by minimizing process errors.

In addition, it serves as a basis for forming the vertical channel structure of the first transistor 100 in a subsequent process, and enables implementation of the three-dimensional vertical structure of the entire 2T memory cell. This vertical structure plays a key role in increasing planar integration density and improving device performance.

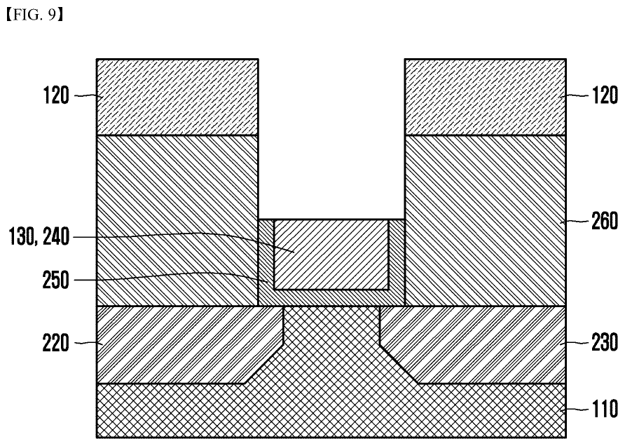

FIG. 9 is a cross-sectional view illustrating a step of recessing the second gate insulating film 250 in a method of manufacturing a 2T memory cell according to an embodiment of the present disclosure.

Referring to FIG. 9, the method of manufacturing a 2T memory cell according to an embodiment of the present disclosure may include performing a selective etch-back of the second gate insulating film 250 shown in FIG. 8.

The second gate insulating film 250 is essential for electrical insulation between the channel region of the second transistor 200 and the second gate 240, but does not need to extend to the upper region of the second gate 240.

The method of manufacturing a 2T memory cell according to an embodiment of the present disclosure includes performing an etch-back to selectively remove the second gate insulating film 250 in the upper region of the second gate 240.

The etch-back process may be performed using an etchant or etching gas having a high selectivity with respect to the material of the second gate insulating film 250.

Through the etch-back process of the gate insulating film 250, the method of manufacturing a 2T memory cell according to an embodiment of the present disclosure enables direct electrical contact between the first channel 140 of the first transistor 100 to be formed in a subsequent process and the second gate 240. This may be essential for the second gate 240 to serve as the drain of the first transistor 100.

Through the etch-back process of the gate insulating film 250, the method of manufacturing a 2T memory cell according to an embodiment of the present disclosure can minimize the contact resistance between the second gate 240 and the first channel 140, which can contribute to improving the electrical characteristics of the device.

In addition, the method of manufacturing a 2T memory cell according to an embodiment of the present disclosure can optimize the electrical connection between the first transistor 100 and the second transistor 200 while maintaining the self-aligned structure through the etch-back process of the gate insulating film 250.

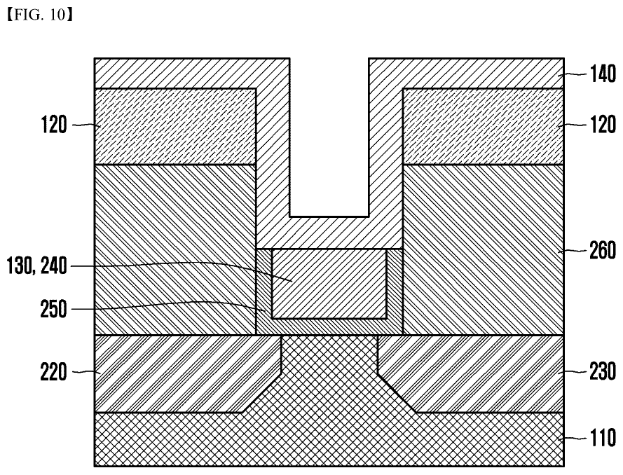

FIG. 10 is a cross-sectional view illustrating a step of forming the first channel 140 of the first transistor 100 on the second gate 240 in a method of manufacturing a 2T memory cell according to an embodiment of the present disclosure.

Referring to FIG. 10, the method of manufacturing a 2T memory cell according to an embodiment of the present disclosure includes depositing a semiconductor material layer for forming the first channel 140 on the second gate 240.

The first channel 140 may be formed by depositing a semiconductor material such as polysilicon or IGZO through chemical vapor deposition (CVD) or atomic layer deposition (ALD).

According to embodiments, when polysilicon is used for the first channel 140, it may be formed by depositing amorphous silicon through low pressure chemical vapor deposition (LPCVD) and then through a crystallization process, and electrical characteristics may be adjusted through impurity doping as needed.

In addition, according to embodiments, when IGZO is used for the first channel 140, it may be formed through sputtering or atomic layer deposition, and since it has a wider energy bandgap (about 3.2 eV) than silicon, data storage characteristics can be improved.

The first channel 140 is formed in a vertical direction to secure a long effective channel length. The vertical channel structure can implement a longer channel length even with the same planar area compared to a planar structure, and is very effective in improving charge storage capability and data retention characteristics.

In particular, the vertical height of the first channel 140 can be an important design parameter that determines the control capability of the first gate and the charge storage characteristics to be formed in a subsequent process.

The structure formed by the self-aligned method of the method of manufacturing a 2T memory cell according to an embodiment of the present disclosure ensures that the first channel 140 is in accurate contact with the second gate 240. Since the second gate 240 simultaneously serves as the gate electrode of the second transistor 200 and the first drain 130 of the first transistor 100, accurate alignment between them directly affects the electrical characteristics and reliability of the device.

The formed vertical channel structure shown in FIG. 10 serves as a basis for forming the first gate insulating film 150 and the first gate of the first transistor 100 in a subsequent process, and can ultimately be a key element for completing the three-dimensional vertical structure of a high-performance 2T memory cell.

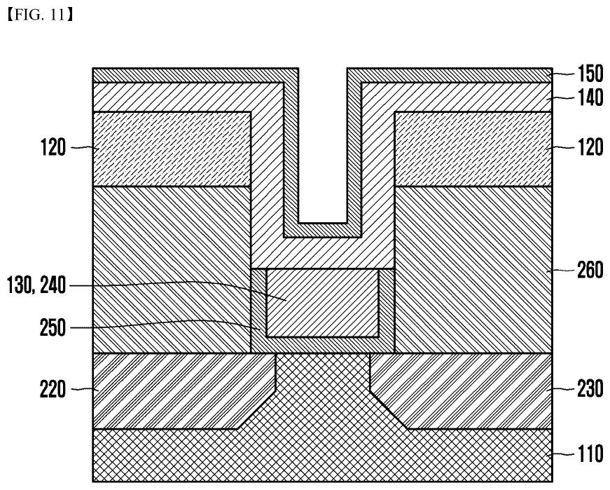

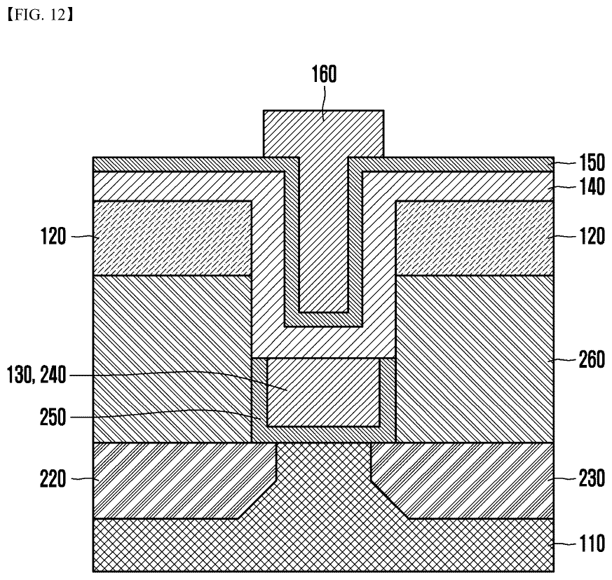

FIGS. 11 and 12 are cross-sectional views illustrating a step of completing the entire structure including the gate structure of the first transistor 100 in a method of manufacturing a 2T memory cell according to an embodiment of the present disclosure.

Referring to FIG. 11, the method of manufacturing a 2T memory cell according to an embodiment of the present disclosure forms the first gate insulating film 150 on the sidewalls and top of the first channel 140 shown in FIG. 10.

The first gate insulating film 150 may be formed of a silicon oxide film, a high-k dielectric material, or a stacked structure thereof, and can function to provide electrical insulation between the first channel 140 and the first gate 160 shown in FIG. 12.

The thickness and material characteristics of the first gate insulating film 150 can determine the threshold voltage and gate control capability of the device.

Referring to FIG. 12, the method of manufacturing a 2T memory cell according to an embodiment of the present disclosure deposits a first gate material on the sidewalls and top of the first gate insulating film 150, and forms the first gate 160 through etching after patterning.

The lower second transistor 200 is dedicated to the read operation of the memory cell, and the upper first transistor 100 is responsible for the write and erase operations. The long channel length of the first transistor 100 improves the retention capability of stored charge, which can improve the data retention characteristics of the memory cell.

The 2T memory cell manufactured through the method of manufacturing a 2T memory cell according to an embodiment of the present disclosure is formed by a self-aligned method to minimize process errors, and high integration is possible through a vertical stacked structure.

The vertical channel structure of the first transistor 100 and the optimized structure of the second transistor 200 enable high-performance memory operation, which can be utilized as a next-generation memory device.

In particular, the structure of the 2T memory cell according to an embodiment of the present disclosure can simultaneously achieve improved data retention characteristics and high-speed operation characteristics compared to conventional DRAM or SRAM, and can bring simplification of the manufacturing process and improvement of reliability through the self-aligned process.

According to one embodiment, the cell area can be minimized by vertically stacking two transistors.

According to one embodiment, by providing a separate read transistor, data destruction during a read operation can be prevented, thereby improving memory bandwidth.

According to one embodiment, by forming the channel of the write transistor vertically, a sufficient effective channel length can be secured to improve data retention time.

According to one embodiment, the channel structures of the write transistor and the read transistor can be independently optimized, thereby improving respective operation characteristics.

According to one embodiment, transistors having a vertical structure can be accurately aligned and manufactured through a self-aligned process.

According to one embodiment, leakage current can be effectively reduced by using a semiconductor material having a wide bandgap such as IGZO as the channel of the write transistor.

According to one embodiment, process compatibility can be secured and manufacturing costs can be reduced by utilizing the existing gate-last process.

According to one embodiment, stable operation characteristics can be secured despite the vertical structure, thereby implementing a highly reliable memory device.

Although the present disclosure has been described through limited examples and drawings, the present disclosure is not intended to be limited to the examples. Those skilled in the art will appreciate that various modifications, additions and substitutions are possible, without departing from the scope and spirit of the disclosure. Therefore, the scope of the present disclosure should not be limited to the described examples, but should be defined not only by the claims described below but also by equivalents of these claims.

What is claimed is:

1. A 2T memory cell, comprising:
a first transistor including a first source, a first gate, and a first drain; and
a second transistor formed on a substrate and including a second source, a second gate, and a second drain,
wherein the first transistor is formed vertically on an upper portion of the second transistor,
wherein the first drain of the first transistor operates as the second gate of the second transistor,
wherein the first transistor performs write and erase operations of data, and the second transistor performs a read operation of the data, and
wherein a channel of the first transistor has a longer effective channel length than a channel of the second transistor.

2. The 2T memory cell of claim 1, wherein the channel of the first transistor is formed of polysilicon or IGZO.

3. The 2T memory cell of claim 1, wherein the second transistor is formed on the substrate of bulk silicon.

4. The 2T memory cell of claim 1, wherein the channel of the first transistor is formed vertically to extend the effective channel length.

5. The 2T memory cell of claim 1, wherein the first transistor is formed by a self-aligned process.

6. The 2T memory cell of claim 1, wherein the channel of the first transistor is formed of a semiconductor material having a wider energy bandgap than the channel of the second transistor.

7. A method of manufacturing a 2T memory cell, the method comprising:
sequentially forming a dummy oxide film, a dummy gate, and a hard mask on a substrate;
patterning the dummy gate using the hard mask;
forming a source and a drain of a second transistor on both sides of the patterned dummy gate;
forming a source of a first transistor on upper portions of both sides of the dummy gate;
removing the hard mask and the dummy gate to form an opening;
forming a gate insulating film and a gate of the second transistor in the opening;
forming a channel of the first transistor vertically on the gate of the second transistor, wherein the gate of the second transistor is formed to serve as a drain of the first transistor; and
forming a gate insulating film and a gate of the first transistor on a side surface of the channel.

8. The method of claim 7, further comprising performing ion implantation for adjusting a threshold voltage of the second transistor before forming the dummy oxide film on the substrate.

9. The method of claim 7, wherein the channel of the first transistor is formed of polysilicon or IGZO.

10. The method of claim 7, further comprising forming an insulating film on an entire structure including the dummy gate and planarizing the insulating film after forming the source and the drain of the second transistor.

11. The method of claim 7, wherein the step of forming the channel of the first transistor is performed through a self-aligned process.

12. The method of claim 7, wherein the source of the first transistor is formed of doped polysilicon or a metal material.

13. The method of claim 7, wherein the channel of the first transistor is formed to have a longer effective channel length than the channel of the second transistor.

14. The method of claim 9, wherein when the channel of the first transistor is formed of IGZO, the IGZO has a wider bandgap than silicon.
